(19) United States
(12) Patent Application Publication
(10) Pub. No.: US 2008/0072955 A1
(43) Pub. Date: Mar. 27, 2008

(54) Photovoltaic cell

(76) Inventor: Charles H. Graham JR., St. Catharines (CA)

Correspondence Address: Sandra J. Thompson, 335 Knoch Knolls Rd., Naperville, IL, 60565, US

(21) Appl. No.: 11/900,538

(22) Filed: Sep. 12, 2007

Related U.S. Application Data
(60) Provisional application No. 60/844,068, filed on Sep. 12, 2006.

(51) Int. Cl. H01L 31/068; H01L 31/04

(52) U.S. Cl. 136/255; 136/252

(57) ABSTRACT

A photovoltaic cell with improved light spectrum sensitivity. The cell is made of layers positioned adjacent to one another; with the layers, in order, consisting of: a collector device; a layer of a p-type halogen salt of silver; a layer of an n-type halogen salt of silver; and an emitter device; wherein the halogen salts are preferably either silver bromide or silver chloride, and which halogen salts act as anode and cathode.

### CROSS-REFERENCE TO RELATED APPLICATIONS

This application claims benefit of Provisional Appl. 60/844,068, filed Sep. 12, 2006.

### TECHNICAL FIELD

The present invention relates to photovoltaic cells, and more particularly to photovoltaic cells which use silver halides to provide improved light sensitivity

### BACKGROUND OF THE INVENTION

While solar cell technology has been progressing for many years, most of the existing technology has been concerned with improving solar cells that use silicon as the cell material. Newer advances have dealt with other materials such as gallium arsenide, copper indium diselenide, and cadmium telluride. However, with silicon and the other materials presently being used for solar cells, efficiencies are low, usually lower than fifteen percent.

### OBJECTS AND SUMMARY OF THE INVENTION

An object of the present invention is to improve the efficiencies of solar cells by allowing the conversion of a wide range of wavelengths of light into energy, therein providing a photovoltaic cell with improved light spectrum sensitivity.

In accordance with this invention the photovoltaic cell is made of layers 30 positioned adjacent to one another; with the layers, in order, consisting of: a collector device; a layer of a p-type halogen salt of silver; a layer of an n-type halogen salt of silver; and an emitter device; the halogen salts being preferably either silver bromide or silver chloride, but possibly silver fluoride or silver iodide, and which halogen salts act as anode and cathode. The silver ions that form are made to migrate by the use of an electric priming current.

### BRIEF DESCRIPTION OF THE FIGURES

FIG. 1 is a sectional view of a photovoltaic cell composed of four layers.

FIG. 2 is a sectional view of a photovoltaic cell composed of eight layers.

### DETAILED DESCRIPTION

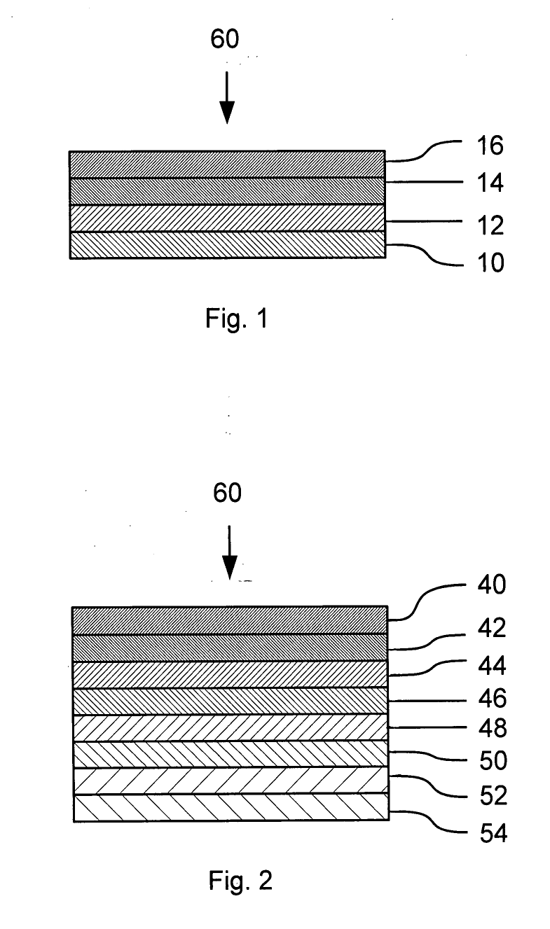

FIG. 1 shows a photovoltaic cell composed of four layers, adjacent to one another, in the following order: a collector device 10, a p-type layer 12 of a halogen salt of silver, an n-type layer 14 of the halogen salt of silver, and an emitter device 16. The collector device can be a plate, grid, fingers or other device suitable for collecting electrons. The emitter device can be in the form of a plate, grid, fingers or other device suitable for emitting electrons. Sunlight 60 shines on the emitter surface of the device.

The halogen salts of silver are preferably either silver bromide or silver chloride but possibly silver fluoride or silver iodide. The p-type layer or, simply, p-layer acts as an anode in the cell, while the n-type layer or n-layer acts as a cathode.

FIG. 2 shows a photovoltaic cell composed of eight layers, adjacent to one another, in the following order: an emitter device 40, an n-type layer of one type of a first halogen salt of silver 42; a p-type layer 44 of the first halogen salt of silver, a collector device 46, an emitter device 48, an n-type layer 50 of a second halogen salt of silver, a p-type layer of the second halogen salt of silver 52, and a collector device, 54. Sunlight 60 shines on the first emitter surface of the device.

The n-type layer in either cell can alternatively be made of a neutral substance coated with an n-type halogen salt of silver, and the p-type layer in either cell can be made of a neutral substance coated with a p-type halogen salt of silver.

When initially activating the cell, there could be created an imbalance of silver and salt ions that could cause the cell to darken, and reduce its effectiveness and efficiency. Priming the cell with a DC voltage would alleviate this by removing the radicals to a collector or emitter device, and lightening the cell. The priming DC voltage could be varied, if required, in order to determine an effective priming voltage. If the cell still darkens, temporary devices could be used to collect the excess ions. If temporary devices are used, they are located adjacent to exposed portions of the n-type and p-type layers. The temporary devices, emitters and collectors in temporary use, have the capability of being removed from the cell.

The initial priming of the cell must be done with an electrical current of voltage potential equal to or higher than the eV of the silver salts or the voltage to be delivered by the cell. This priming could be done with an external source of variable current and/or variable voltage. The priming current would help in aligning the atoms and ions, thereby decreasing the internal losses by simplifying the flow of electrons through a straighter or easier path. This priming could either be done in darkness or in the presence of light. If darkness gives the best results, because it precludes or prevents stray or unaligned silver ions or radicals, the external priming may have to be maintained until exposure to light. After light exposure, the cell itself produces its own electrically charged field and an autonomous current starts to flow. It may be that priming with a larger current may have to be done only once at start-up because the necessary voltage or current to set up the ions or radicals may have to be of a given amount while the voltage or current needed to maintain the ions or radicals in the set up position may be much smaller.

Once the ions have been made to migrate to an emitter or collector device through the creation of an electrical (voltage) potential, they would either remain there by maintaining the polarity or voltage or, when the temporary device is used, be pulled out of the cell. At night, if there is no generation by the residual light, that voltage potential should be maintained by an external source.

Also the voltage to be delivered to prime the cell mentioned earlier should create an alignment of the free atoms and ions in the material. This internal alignment of particles will lower the internal resistance of the cell, thereby reducing internal cell losses. This is caused by the fact that silver is a much better conductor than most other materials.

The use of halogen salts of silver would increase the sensitivity of the photovoltaic cell to a greater light spectrum than the cells in use now. The cells could be made sensitive from infrared to ultraviolet light and to x-rays and possibly gamma rays.

Halogen salts are chemically active and subject to reaction. Because of this, the cell could be assembled in an environment which will prevent many possible unwanted reactions, such as a noble gas environment. Any void spaces in the cell could be filled with a noble gas.

The energy required to release the electrons may vary with priming voltage. In other words the attachment force of the electrons may be modified by changes in the priming voltage and current. It is not known if the change in the attachment force remains constant or varies once the autonomous process takes over.

Doping of the cells will likely be required. The doping is typically done with boron and phosphorus, but any other appropriate dopant could be used. The layer doped with phosphorous or other appropriate element is called the n-type layer or the n-layer; the layer doped with boron or other appropriate element is called the p-type layer or the p-layer. Therefore, doping a layer of a halogen salt of silver with phosphorous or other appropriate element would result in an n-type layer of the halogen salt of silver, while doping a layer of the halogen salt of silver with boron or other appropriate element results in a p-type layer of the halogen salt of silver.

Excess electrons accumulate in the n-layer, which then attracts more electrons, which process, in turn, gives a larger negative charge. If there is an electric circuit, these electrons flow to the p-layer, which has a positive charge or lack of electrons. The process of doping the cell creates a junction or barrier between the n-layer and the p-layer. The thickness of the n-layer must be such that it will allow conductivity. The thickness of this layer can also be dictated by efficiency or economic factors.

It is possible that priming the cell could also be a mechanism for the creation of this junction or p-n barrier, which would result in the formation of the p-layer and the n-layer. If this is the case, doping may not be necessary, but may increase the efficiency of the cell.

The internal resistance could also be affected by the purity of the silver halogen salts because of the resistance generated by the impurities, so the salt's purity should be as high as practicality will allow considering cost effectiveness.

Other considerations would apply such as the design of the physical structure and the shape of the cell. These could include but are not limited to a crystal wafer, a colloidal solution or any other conduction solution or vapor applied to a plastic flexible film or rigid plate if this process is feasible with these compounds.

While a preferred form of this invention has been described above and shown in the accompanying drawings, it should be understood that applicant does not intend to be limited to the particular details described above and illustrated in the accompanying drawings, but intends to be limited only to the scope of the invention as defined by the following claims. In this regard, the term “means for” as used in the claims is intended to include not only the designs illustrated in the drawings of this application and the equivalent designs discussed in the text, but it is also intended to cover other equivalents now known to those skilled in the art, or those equivalents which may become known to those skilled in the art in the future.

What is claimed is:

1. A photovoltaic cell made up of layers positioned adjacent to one another; with the layers, in order, consisting of:
a collector device;
a layer of a p-type halogen salt of silver;
a layer of an n-type halogen salt of silver; and
an emitter device;
and in which the p-type layer of the halogen salt of silver acts as an anode and the n-type layer of the halogen salt of silver acts as a cathode.

2. A photovoltaic cell made of layers positioned adjacent to one another; with the layers, in order, consisting of:
a collector device;
a layer of a neutral substance coated with a p-type halogen salt of silver;
a layer of a neutral substance coated with an n-type halogen salt of silver; an emitter device;
and in which the p-type halogen salt of silver acts as an anode and the n-type layer of the halogen salt of silver acts as a cathode.

3. A photovoltaic cell made of layers positioned adjacent to one another; with the layers, in order, consisting of:
a collector device;
a p-type layer of one type of a halogen salt of silver;
an n-type layer of the same type of halogen salt of silver;
an emitter device;
a collector device;
a p-type layer of a second type of a halogen salt of silver;
an n-type layer of the second type of the halogen salt of silver; and
an emitter device;
and in which the p-type layers act as anodes and the n-type layers act as cathodes.

4. The cell of claim 1, 2 or 3 in which the cell is primed by inducing a voltage potential equal to or higher than the possible voltage to be delivered by the cell.

5. The cell of claim 1, 2 or 3 in which the collector device or devices function to collect electrons which have been displaced.

6. The cell of claim 1, 2 or 3 in which the collector device or devices are supplied with a voltage potential from an external source, also called priming.

7. The cell of claim 1, 2 or 3 in which void spaces in the cell are filled with nitrogen or one of the noble gasses.

8. The cell of claim 1, 2 or 3 in which the p-type layer or layers are formed by doping a layer or layers made of a halogen salt of silver with boron or any other appropriate dopant, to form the p-layer and the n-type layer or layers are formed by doping a second set of layer or layers made of a halogen salt of silver with phosphorus or any other appropriate dopant to form the n-layer.

9. The cell of 1, 2 or 3 in which the n-layer or layers have a critical thickness so the junction between the p-layer and the n-layer will be at an optimum depth for absorbing photons.

10. The cell of 1, 2, or 3 in which there is a temporary emitter plate installed adjacent to the emitter plate and which collects stray silver ions, and which plate is in the form of a grid, bar, fingers, mesh or other appropriate configuration, and which can be removed when it is not needed.
